(19) United States
(12) Patent Application Publication
(10) Pub. No.: US 2025/0093303 A1
(43) Pub. Date: Mar. 20, 2025

(54) SEMICONDUCTOR DEFECT INSPECTION METHOD AND APPARATUS

(71) Applicants: Hyundai Motor Company, Seoul (KR); Kia Corporation, Seoul (KR)

(72) Inventor: Jung Gi Han, Seoul (KR)

(21) Appl. No.: 18/887,837

(22) Filed: Sep. 17, 2024

(30) Foreign Application Priority Data
Sep. 18, 2023 (KR) 10-2023-0123906

(51) Int. Cl. G01N 29/04; G01N 1/34; G01N 1/44

(52) U.S. Cl. CPC G01N 29/04; G01N 1/34; G01N 1/44; G01N 2291/0231; G01N 2291/0289

(57) ABSTRACT

A method and an apparatus for inspecting defects in semiconductors may be incorporated in a vehicle production process. The apparatus includes an exterior inspection unit for inspecting an exterior of a semiconductor, a function inspection unit for inspecting functions of the semiconductor, a first ultrasonic inspection unit for performing a first ultrasonic inspection on the semiconductor, a pretreatment tester for performing a pretreatment on the semiconductor when the first ultrasonic inspection has been completed, a second ultrasonic inspection unit for performing a second ultrasonic inspection on the semiconductor when the pretreatment has been completed, and a cross-sectional inspection unit for inspecting a cross-section of the semiconductor when the second ultrasonic inspection shows that delamination has increased after the pretreatment.

### CROSS-REFERENCE TO RELATED APPLICATION

The present application claims under 35 U.S.C. § 119(a) the benefit of Korean Patent Application No. 10-2023-0123906, filed on Sep. 18, 2023, the entire contents of which are incorporated by reference herein.

### BACKGROUND

### (a) Technical Field

The present disclosure relates to a method and apparatus for inspecting defects in semiconductors.

### (b) Description of the Related Art

Recently, semiconductor devices increasingly have been used for vehicle production because of the proliferation of electronics of vehicles. It is important to ensure the reliability of semiconductors used for vehicle production because defects in such semiconductors can lead to accidents such as sudden vehicle acceleration.

Ultrasonic inspection is performed to detect defects in semiconductors, and when it is determined that delamination has occurred on leads inside a semiconductor, the verification of reliability, which may take around two months, is carried out to determine whether the semiconductor is defective.

After spending around two months conducting the verification of the reliability of semiconductors, approximately one percent or less of the semiconductors typically are found to be defective. In other words, the verification of reliability typically results in delaying vehicle shipments and wasting significant costs in the process. Therefore, there is a need for a solution to this problem.

The information included in this Background of the present disclosure section is only for enhancement of understanding of the general background of the present disclosure and may not be taken as an acknowledgement or any form of suggestion that this information forms the prior art already known to a person skilled in the art.

### SUMMARY

In order to solve the above-mentioned problem, the present disclosure provides a method of inspecting defects in semiconductors, where before the verification of the reliability of the semiconductors, which typically requires a lot of time, the cross-section of the semiconductors may be analyzed to see whether delamination has occurred on leads inside the semiconductors, so that the verification of reliability may be carried out only on semiconductors with delamination on their lead, thereby dramatically shortening the time to inspect defects in the semiconductors.

A method of inspecting defects in a semiconductor according to at least one embodiment of the present disclosure may include inspecting an exterior of a semiconductor, inspecting functions of the semiconductor, performing a first ultrasonic inspection on the semiconductor, performing a pretreatment on the semiconductor, performing a second ultrasonic inspection on the semiconductor for which the pretreatment has been completed, and inspecting a cross-section of the semiconductor when the second ultrasonic inspection shows that delamination has increased after the pretreatment.

According to at least one embodiment of the present disclosure, during the inspecting of the cross-section, the cross-section of a lead portion of the semiconductor is inspected.

According to at least one embodiment of the present disclosure, the inspection of the cross-section of the lead portion may be carried out through an ion milling equipment.

The method according to at least one embodiment of the present disclosure may further include performing a verification of reliability of the semiconductor when it is determined that delamination has occurred on the cross-section of the lead portion after the inspecting of the cross-section.

The method according to at least one embodiment of the present disclosure may further include determining that the semiconductor is defect-proof when it is determined that delamination has occurred under a preset delamination level on the cross-section of the lead portion after the inspecting of the cross-section.

According to at least one embodiment of the present disclosure, the verification of the reliability may include a temperature and cycle test, and the temperature and cycle test may include a heat shock test.

According to at least one embodiment of the present disclosure, the heat shock test may be performed under conditions of 1,000 cycles to 2,000 cycles and a temperature of −55° C. to 125° C.

The method according to at least one embodiment of the present disclosure may further include performing a third ultrasonic inspection after the performing of the verification of the reliability.

The method according to at least one embodiment may be incorporated into a vehicle production process.

An apparatus for inspecting defects in a semiconductor according to at least one embodiment of the present disclosure may include an exterior inspection unit configured to inspect an exterior of a semiconductor, a function inspection unit configured to inspect functions of the semiconductor, a first ultrasonic inspection unit configured to perform a first ultrasonic inspection on the semiconductor, a pretreatment tester configured to perform a pretreatment on the semiconductor when the first ultrasonic inspection has been completed, a second ultrasonic inspection unit configured to perform a second ultrasonic inspection on the semiconductor when the pretreatment has been completed, and a cross-sectional inspection unit configured to inspect a cross-section of the semiconductor when the second ultrasonic inspection shows that delamination has increased after the pretreatment.

According to at least one embodiment of the present disclosure, the cross-sectional inspection unit may inspect the cross-section of a lead portion of the semiconductor.

According to at least one embodiment of the present disclosure, the inspection of the cross-section of the lead portion may be carried out through an ion milling equipment.

The apparatus according to at least one embodiment of the present disclosure may further include a reliability verification unit configured to perform a verification of reliability of the semiconductor, and, when the cross-sectional inspection unit determines that delamination has occurred on the cross-section of the lead portion, the verification of the reliability of the semiconductor may be carried out through the reliability verification unit.

According to at least one embodiment of the present disclosure, the cross-sectional inspection unit determines that the semiconductor is defect-proof when it is determined that delamination has occurred under a preset delamination level on the cross-section of the lead portion.

According to at least one embodiment of the present disclosure, the reliability verification unit may perform a temperature and cycle test, and the temperature and cycle test may include a heat shock test.

According to at least one embodiment of the present disclosure, the heat shock test may be performed under conditions of 1,000 cycles to 2,000 cycles and a temperature of −55° C. to 125° C.

The apparatus according to at least one embodiment of the present disclosure may further include a third ultrasonic inspection unit configured to perform a third ultrasonic inspection on the semiconductor.

According to at least one embodiment of the present disclosure, the third ultrasonic inspection unit may perform the third ultrasonic inspection when the verification of the reliability has been completed through the reliability verification unit.

According to at least one embodiment of the present disclosure, the apparatus may be incorporated into a vehicle production line, i.e., vehicle manufacturing carried out at a factory or other facility.

According to the present disclosure, before the verification of the reliability of semiconductors, which requires a lot of time, the cross-section of the semiconductors may be analyzed to see whether delamination has occurred on lead inside the semiconductors, so that the verification of the reliability may be carried out only on semiconductors with delamination on their lead, thereby dramatically shortening the time to inspect defects in the semiconductors.

The effects of the present disclosure are not limited to the above-mentioned effects, and the following description would allow a person having ordinary skill in the technical field to which the present disclosure pertains to clearly understand other effects not mentioned above.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 shows an apparatus for inspecting defects in a semiconductor according to an embodiment of the present disclosure.

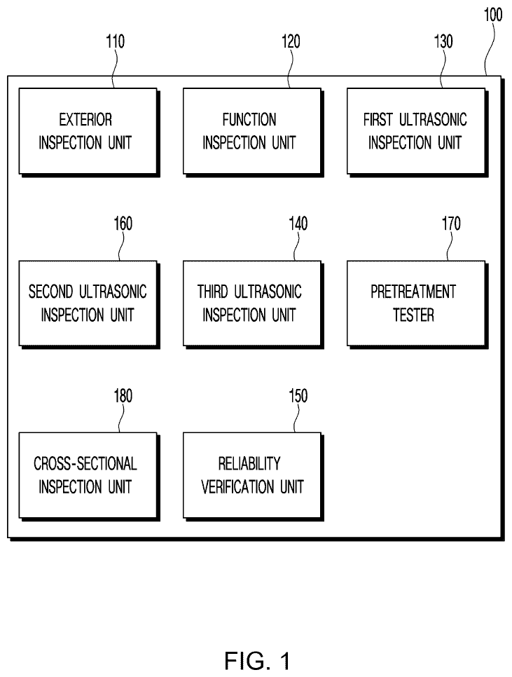

FIG. 2 shows how first to third ultrasonic inspection units of the apparatus for inspecting defects in a semiconductor according to an embodiment of the present disclosure inspect an air layer or delamination in a semiconductor using ultrasonic waves.

FIG. 3 shows test conditions for each MSL level for a pretreatment test conducted by the apparatus for inspecting defects in a semiconductor according to an embodiment of the present disclosure.

FIG. 4 shows a baking chamber, a soaking chamber, and a reflow oven of a pretreatment tester of the apparatus for inspecting defects in a semiconductor according to an embodiment of the present disclosure.

FIG. 5 is a flow chart for showing a process of inspecting defects in a semiconductor according to an embodiment of the present disclosure.

FIG. 6 shows a cross-section of a lead portion and a marked delamination portion found during an ultrasonic inspection in the process of inspecting defects in a semiconductor according to an embodiment of the present disclosure.

FIGS. 7A through 7C show cross-sections of the interface between a molding material and a wire of a lead portion along with the interface without delamination and the interface with delamination in the process of inspecting defects in a semiconductor according to an embodiment of the present disclosure.

It may be understood that the appended drawings are not necessarily to scale, presenting a somewhat simplified representation of various features illustrative of the basic principles of the present disclosure. The specific design features of the present disclosure as included herein, including, for example, specific dimensions, orientations, locations, and shapes, will be determined in part by the particularly intended application and use environment.

In the figures, the same reference numerals refer to the same or equivalent parts of the present disclosure throughout the several figures of the drawing.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Because various changes can be made to the present disclosure and a range of embodiments can be made for the present disclosure, specific embodiments will be illustrated and described in the drawings. However, this is not intended to limit the present disclosure to the specific embodiments, and it should be understood that the present disclosure includes all changes, equivalents, and substitutes within the technology and the scope of the present disclosure.

Terms containing ordinal numbers such as “first” and “second” may be used to describe various components, but the components are not limited by the terms. The above-mentioned terms are used only for the purpose of distinguishing one component from another component.

When a component is said to be “coupled” or “connected” to another component, it means that the component may be directly coupled or connected to the other component or there may be other components therebetween. On the other hand, when a component is referred to as being “directly coupled” or “directly connected” to another component, it means that there are no other components therebetween.

When each layer or film, region, pattern, or structure is described to be “on/above” or “under/below” each substrate, layer or film, region, pad, or pattern in the description of the embodiments of the present disclosure, it means that it is directly thereon or thereunder, or thereon or thereunder with another layer therebetween. Whether one component is “on/above” or “under/below” another component is determined for convenience based on how they are shown in the drawing. Such expressions are only used for convenience to indicate how components are positioned with respect to each other, and should not be understood as limiting the actual positions of the components. For example, the statement “B on A” simply indicates that B is positioned on A in the drawing, unless otherwise stated or the nature of A or B does not necessarily require that A be located on B, and, in actual products, etc., B may be positioned under A, or B and A may be placed side by side.

In addition, the thickness or size of each layer or film, region, pattern, or structure may be changed in the drawings for clarity and convenience of description, and the actual size thereof is not entirely reflected.

Unless otherwise defined, all terms used herein, including technical or scientific terms, have meanings commonly understood by a person having ordinary skill in the technical field to which the present disclosure pertains. Terms defined in commonly used dictionaries should be interpreted as having meanings consistent with the meanings they have in the context of the relevant technology, and should not be interpreted in an ideal or overly formal sense unless explicitly defined in the present disclosure.

Hereinafter, the embodiments of the present disclosure will be described in detail with reference to the attached drawings. Components identical or corresponding to one other have the same reference number regardless of their drawing reference numbers, and the description thereof will not be repeatedly provided.

An apparatus 100 for detecting defects in a semiconductor according to an embodiment of the present disclosure may include an exterior inspection unit 110, a function inspection unit 120, a first ultrasonic inspection unit 130, a pretreatment tester 160, a second ultrasonic inspection unit 140, a cross-sectional inspection unit 170, a reliability verification unit 180, and a third ultrasonic inspection unit 150.

The exterior inspection unit 110 may be an apparatus for inspecting the exterior of a semiconductor. Inspection of the exterior of semiconductors may be carried out using optical equipment such as a microscope.

The function inspection unit 120 may be an apparatus for inspecting the basic functions of semiconductors, and equipment for the inspection may vary depending on the type of semiconductor. Details on the inspection of the functions will be described below.

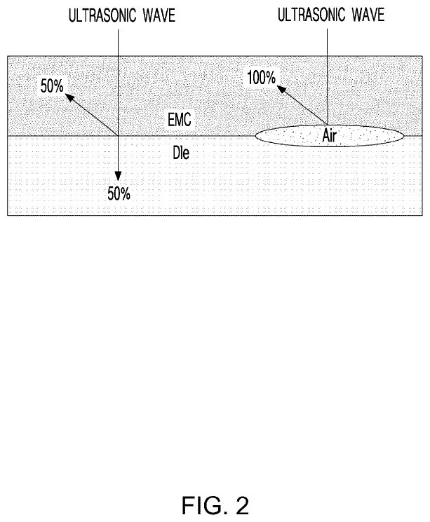

As shown in FIG. 2, when the first ultrasonic inspection unit 130 has radiated ultrasonic waves on the surface of a semiconductor and determined that there may be delamination on an internal interface, it may reflect 100 percent of the ultrasonic waves to find out whether there is really the delamination thereon.

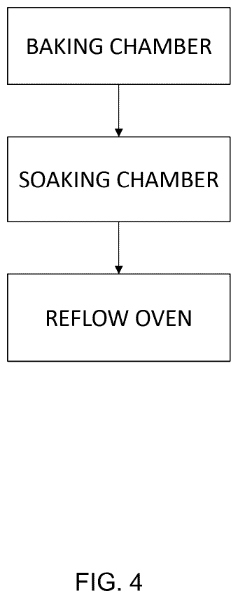

As shown in FIG. 4, the pretreatment tester 160 may be an apparatus that tests a semiconductor under conditions according to the corresponding MSL level by sequentially introducing the semiconductor into a baking chamber, a soaking chamber, and a reflow oven included in the pretreatment tester 160.

Because the second ultrasonic inspection unit 140 and the third ultrasonic inspection unit 150 may be the same as the first ultrasonic inspection unit 130, detailed descriptions thereof will not be provided. In an embodiment of the present disclosure, the first to third ultrasonic inspection units 130 to 150 may be integrated in one unit to perform the first to third ultrasonic inspections.

The cross-sectional inspection unit 170 may be an apparatus that inspects the cross-section of the lead portion of a semiconductor, and may determine whether the wire has been damaged by intensively analyzing the cross-section of the portion where delamination has occurred on the semiconductor lead. There are various types of equipment to inspect the cross-section of the lead portion of a semiconductor, including equipment that analyzes it by a direct grinding, equipment that analyzes it using ions, etc.

The reliability verification unit 180 may be an apparatus that verifies whether delamination occurs between materials inside a semiconductor by increasing the stress on the semiconductor while conducting a temperature and cycle test. Details on the reliability verification unit 180 will be described below.

Next, a method of detecting defects in a semiconductor according to an embodiment of the present disclosure will be described.

The method of detecting defects in a semiconductor according to an embodiment of the present disclosure may include a step of inspecting the exterior of the semiconductor, a step of checking the functions of the semiconductor for which the inspection of the exterior has been completed, a step of performing a first ultrasonic inspection on the semiconductor for which the inspection of the functions has been completed, a step of performing a pretreatment test on the semiconductor for which the first ultrasonic inspection has been completed, a step of performing a second ultrasonic inspection on the semiconductor for which the pretreatment test has been completed, and a step of inspecting the cross-section of the semiconductor when the second ultrasonic inspection shows that delamination has increased after the pretreatment test.

In the step of inspecting the exterior of a semiconductor, the exterior of the semiconductor may be inspected through a microscope, and defects observed on the exterior may be visually inspected. Since semiconductors are small in size and their main components are also small in size, the components are inspected through a microscope to see whether there are any defects on their exterior.

In the step of checking the functions of the semiconductor for which the inspection of the exterior has been completed, the basic functions of the semiconductor may be checked, and it may be determined whether the semiconductor performs the functions for achieving the purpose for which it has been manufactured.

In the step of performing the first ultrasonic inspection on the semiconductor for which the inspection of the functions has been completed, the inspection may be conducted through a non-destructive analysis using ultrasonic waves to analyze the gap on the interface between materials inside the semiconductor.

As mentioned above and shown in FIG. 2, during the ultrasonic inspection, when ultrasonic waves have been radiated on the surface of a semiconductor and it has been determined that there may be delamination on an internal interface, 100 percent of the ultrasonic waves may be reflected to find out whether there is really the delamination thereon.

After comparing the sizes of a delamination area measured before and after the verification of reliability, which will be described below, during the ultrasonic inspection, a detailed analysis may be intensively carried out when there is a change in size.

In the step of performing the pretreatment test on a semiconductor for which the ultrasonic inspection has been completed, the process of mounting or soldering the semiconductor on a PCB may be simulated.

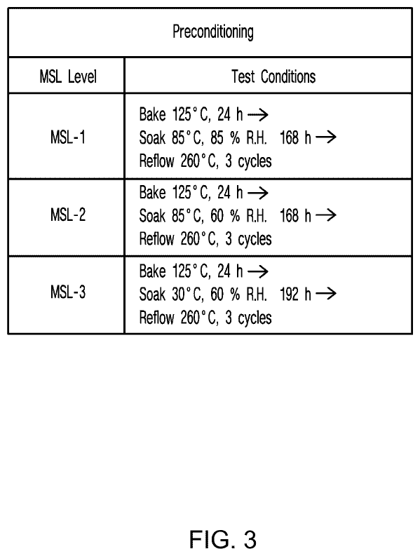

As mentioned above and shown in FIG. 3, the pretreatment test may be conducted under conditions according to the MSL level specified for each semiconductor. In addition, as shown in FIG. 4, to conduct the pretreatment test, a semiconductor may be sequentially introduced into the baking chamber, the soaking chamber, and the reflow oven included in the pretreatment tester 160 to be tested under conditions according to the corresponding MSL level.

The step of performing the second ultrasonic inspection on the semiconductor for which the pretreatment test has been completed may involve the same process as the step of performing the first ultrasonic inspection on the semiconductor for which the inspection of the functions has been completed, so no detailed description thereof will be provided.

There is a difference between the first ultrasonic inspection and the second ultrasonic inspection in that the first ultrasonic inspection may be to inspect delamination inside a semiconductor before the pretreatment test and the second ultrasonic inspection may be to check how much the delamination observed during the first ultrasonic inspection has increased after the pretreatment test.

When delamination is found to have increased after the pretreatment test as a result of the second ultrasonic inspection, the cross-section of the lead portion of the semiconductor may be inspected using cross-section inspection equipment in the step of inspecting the cross-section of a semiconductor. Specifically, the inspection of the cross-section of the lead portion of the semiconductor may be a process of intensively analyzing the cross-section of the portion where delamination has occurred in the semiconductor lead to determine whether the wire has been damaged.

As mentioned above, there are various types of equipment to inspect the cross-section of the lead portion of a semiconductor, including equipment that analyzes it by a direct grinding, equipment that analyzes it using ions, etc.

The inspection equipment according to this embodiment may be an ion milling equipment that uses argon gas and does not apply physical shock, so the analyzed cross-section may be very clean.

In addition, it may be possible to accurately inspect only desired portions through automation, making the inspection less likely to fail.

When it is determined that delamination has occurred on the cross-section of the lead portion of a semiconductor in the step of inspecting the cross-section thereof, the method of detecting defects in a semiconductor according to at least one embodiment of the present disclosure may further include the step of verifying the reliability of the semiconductor.

The verifying of the reliability of a semiconductor may include a temperature and cycle test. During the temperature and cycle test, which is the most crucial procedure for the verifying of the reliability, when a semiconductor is placed repeatedly and alternately in high-temperature and low-temperature areas at regular intervals, the materials that make up the semiconductor may contract and expand repeatedly, which may accelerate fatigue and cause destruction in areas with a weak structure. The reliability verification unit 180 may include equipment for the temperature and cycle test, and the equipment may use an elevator therein to move a semiconductor repeatedly and alternately to high-temperature and low-temperature areas, causing the temperature applied to the semiconductor to change rapidly and amplifying the stress on the semiconductor.

The temperature and cycle test may include a heat shock test, for example. The heat shock test may be performed under conditions of 1,000 cycles to 2,000 cycles and a temperature of −55° C. to 125° C.

When the verification of the reliability has been completed, it may be checked through the third ultrasonic inspection whether the delamination found during the first or second ultrasonic inspection has increased. When it is determined that the delamination has not increased, the semiconductor may not be determined to be defective.

When it is not determined that delamination has occurred on the cross-section of the lead portion of a semiconductor in the step of inspecting the cross-section thereof, the method of detecting defects in a semiconductor according to at least one embodiment of the present disclosure may further include a step of not determining that the semiconductor is defective.

When no defects in a semiconductor are detected in the step, that is, when no delamination is found during the inspection of the cross-section of the semiconductor, the semiconductor may not be determined to be defective even without the above-described verification of the reliability. As a result, there may be no need for the verification of the reliability, which takes at least two months.

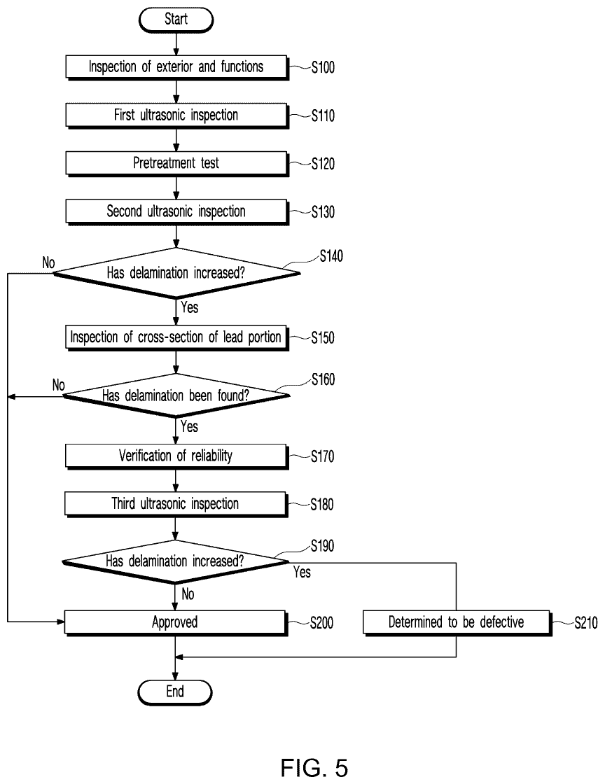

Next, the method of detecting defects in a semiconductor will be described with reference to FIG. 5.

First, the exterior of a semiconductor may be inspected to determine whether there are any defects on the exterior thereof. When the inspection of the exterior of the semiconductor has been completed, the inspection on the functions of the semiconductor may be performed to check whether there are any problems with the functions of the semiconductor at S100.

When the inspection on the functions has been completed, the first ultrasonic inspection may be carried out to determine whether delamination has occurred in the semiconductor at S110.

When the first ultrasonic inspection has been carried out to determine whether delamination has occurred in the semiconductor, the pretreatment test may be conducted at S120. Since the pretreatment test has been described in detail above, no detailed description thereof will be provided.

When the pretreatment test has been completed, the second ultrasonic inspection may be performed to determine how much delamination has increased compared to the first ultrasonic inspection at S130.

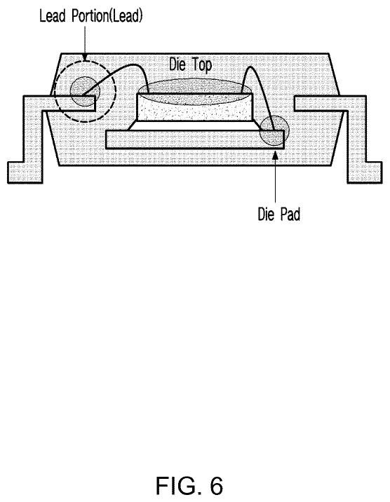

When the second ultrasonic inspection shows that the delamination has not increased or has increased within acceptable limits at S140, the semiconductor may be approved at S200. When the second ultrasonic inspection shows that the delamination has increased beyond the acceptable limits at S140, the cross-section of the lead portion of the semiconductor may be inspected at S150. For an exemplary assumption that delamination occurs at the lead portion shown in FIG. 6 after the pretreatment test, a result of the second ultrasonic inspection may show the delamination.

Because it is determined that the delamination on the lead portion is defective as the result of the ultrasonic inspection, the cross-section of the lead portion may be inspected. Details on the inspection of the cross-section of the lead portion will be described below.

On the other hand, when it is determined that there is no delamination as a result of the inspection of the cross-section of the lead portion at S160, the semiconductor may be approved at S200.

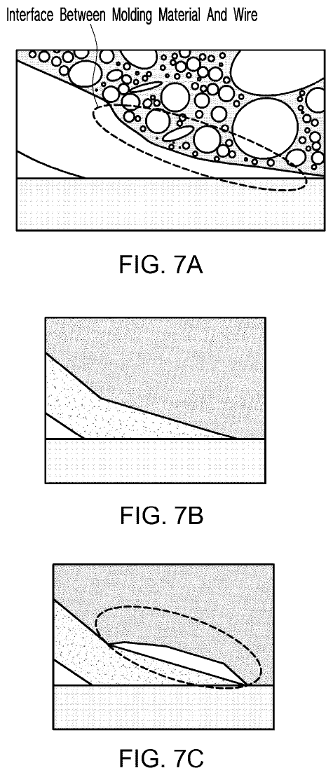

Further to the assumptive example above, when the cross section of the lead portion is inspected after it has been determined that delamination has occurred in the area of the lead portion (see dotted line in FIG. 6) as a result of the ultrasonic inspection, it may be possible to determine whether the delamination has occurred on the interface between a molding material and a wire as shown by the dotted line in FIG. 7A.

Even when delamination has been suspected as a result of the ultrasonic inspection, in many cases, it may be determined that there is no delamination during the inspection of the cross-section of the lead portion, as shown in FIG. 7B. In this case, the semiconductor may be determined to be a good product without any separate verification of reliability.

When the inspection of the cross-section of the lead portion shows that delamination has occurred (marked with the red dotted line) as shown in FIG. 7C at S160, the verification of reliability may be carried out at S170.

Since the verification of reliability has been already described above, no detailed description thereof will be provided.

For semiconductors for which the verification of reliability has been completed, the third ultrasonic inspection may be performed to see whether delamination has increased compared to the second ultrasonic inspection at S180. According to some embodiments of the present disclosure, it may be possible to check whether delamination has occurred through the inspection of the cross-section of the lead portion instead of the third ultrasonic inspection.

When the third ultrasonic inspection or the inspection of the cross-section of the lead portion does not show that delamination has increased in semiconductors for which the verification of reliability has been completed at S190, the semiconductors may be approved at S200.

When the third ultrasonic inspection or the inspection of the cross-section of the lead portion shows that the delamination has increased at S190, the semiconductors may be ultimately determined to be defective and classified as a defective semiconductor at S210.

The description has been made focusing on the embodiments of the present disclosure, but the embodiments are only illustrative and are not intended to limit the present disclosure. A person having ordinary skill in the art would be understand that various modifications and applications that have not been described above can be made to the embodiments within the essential features thereof. For example, each of the components specifically described for the embodiments can be modified. In addition, the differences resulting from such modifications and applications should be deemed to be within the scope of the present disclosure defined by the appended claims.

The foregoing descriptions of the specific exemplary embodiments of the present disclosure have been presented for the purposes of illustration and description. They are not intended to be exhaustive or to limit the present disclosure to the precise forms disclosed, and obviously many modifications and variations are possible in light of the above-described teachings. The exemplary embodiments were chosen and described to explain certain principles of the present disclosure and their practical application, to enable others skilled in the art to make and utilize the various exemplary embodiments of the present disclosure, as well as various alternatives and modifications thereof. It is intended that the scope of the present disclosure be defined by the claims appended hereto and their equivalents.

What is claimed is:

1. A method of inspecting defects in a semiconductor, the method comprising
inspecting, by an exterior inspection unit, an exterior of a semiconductor,
inspecting, by a function inspection unit, functions of the semiconductor,
performing, by a first ultrasonic inspection unit, a first ultrasonic inspection on the semiconductor,
performing, by a pretreatment tester, a pretreatment on the semiconductor,
performing, by a second ultrasonic inspection unit, a second ultrasonic inspection on the semiconductor for which the pretreatment has been completed, and
inspecting, by a cross-sectional inspection unit, a cross-section of the semiconductor when the second ultrasonic inspection shows that delamination has increased after the pretreatment.

2. The method of claim 1, wherein during the inspecting of the cross-section, the cross-section of a lead portion of the semiconductor is inspected.

3. The method of claim 2, wherein the inspection of the cross-section of the lead portion is carried out using ion milling equipment.

4. The method of claim 3, further comprising performing a verification of reliability of the semiconductor when it is determined that delamination has occurred on the cross-section of the lead portion after inspecting the cross-section.

5. The method of claim 3, further comprising determining that the semiconductor is defect-proof when it is determined that delamination has occurred under a preset delamination level on the cross-section of the lead portion after inspecting the cross-section.

6. The method of claim 3, wherein the verification of the reliability includes a temperature and cycle test.

7. The method of claim 6, wherein the temperature and cycle test includes a heat shock test.

8. The method of claim 7, wherein the heat shock test is performed under conditions of 1,000 cycles to 2,000 cycles and a temperature of −55° C. to 125° C.

9. The method of claim 4, further comprising performing a third ultrasonic inspection after performing the verification of the reliability.

10. The method of claim 1, wherein the method of inspecting defects is incorporated into a vehicle production process.

11. An apparatus for inspecting defects in a semiconductor, the apparatus comprising:
an exterior inspection unit configured to inspect an exterior of a semiconductor,
a function inspection unit configured to inspect functions of the semiconductor,
a first ultrasonic inspection unit configured to perform a first ultrasonic inspection on the semiconductor,
a pretreatment tester configured to perform a pretreatment on the semiconductor when the first ultrasonic inspection has been completed,
a second ultrasonic inspection unit configured to perform a second ultrasonic inspection on the semiconductor when the pretreatment has been completed, and
a cross-sectional inspection unit configured to inspect a cross-section of the semiconductor when the second ultrasonic inspection shows that delamination has increased after the pretreatment.

12. The apparatus of claim 11, wherein the cross-sectional inspection unit inspects the cross-section of a lead portion of the semiconductor.

13. The apparatus of claim 12, wherein the inspection of the cross-section of the lead portion is carried out using ion milling equipment.

14. The apparatus of claim 13, further comprising a reliability verification unit configured to perform a verification of reliability of the semiconductor,
wherein when the cross-sectional inspection unit determines that delamination has occurred on the cross-section of the lead portion, the verification of the reliability of the semiconductor is carried out through the reliability verification unit.

15. The apparatus of claim 13, wherein the cross-sectional inspection unit determines that the semiconductor is defect-proof when it is determined that delamination has occurred under a preset delamination level on the cross-section of the lead portion.

16. The apparatus of claim 13, wherein the reliability verification unit performs a temperature and cycle test.

17. The apparatus of claim 16, wherein the temperature and cycle test includes a heat shock test.

18. The apparatus of claim 17, wherein the heat shock test is performed under conditions of 1,000 cycles to 2,000 cycles and a temperature of −55° C. to 125° C.

19. The apparatus of claim 14, further comprising a third ultrasonic inspection unit configured to perform a third ultrasonic inspection on the semiconductor,
wherein the third ultrasonic inspection unit performs the third ultrasonic inspection when the verification of the reliability has been completed through the reliability verification unit.

20. A vehicle production line comprising the apparatus of claim 11.
